(19) United States
(12) Patent Application Publication
(10) Pub. No.: US 2013/0112844 A1
(43) Pub. Date: May 9, 2013

(54) MOUNTING DEVICE FOR HARD DISK DRIVE

(71) Applicant: HUAN-CHIN WANG, Tu-Cheng (TW)

(72) Inventor: HUAN-CHIN WANG, Tu-Cheng (TW)

(73) Assignee: HON HAI PRECISION INDUSTRY CO., LTD., Tu-Cheng (TW)

(21) Appl. No.: 13/418,368

(22) Filed: Mar. 13, 2012

(30) Foreign Application Priority Data
Nov. 8, 2011 (TW) 100140648

(51) Int. Cl. H05K 7/14

(52) U.S. Cl. 248/636

(57) ABSTRACT

A mounting device for mounting a hard disk drive includes a bracket, two shock absorbing members, and a slide member. The bracket includes two opposite side plates. An inner surface of each side plate defines a receiving slot. Each shock absorbing member is made of resilient material and received in the corresponding receiving slots.

Each shock absorbing member defines a groove facing the other shock absorbing member. The slide member includes two mounting plates respectively fixed to opposite sides of the hard disk drive. A mounting portion extends from each mounting plate to slidably engage in the groove of the corresponding shock absorbing member.

### BACKGROUND

1. Technical Field

The present disclosure relates to a device for mounting a hard disk drive (HDD).

2. Description of Related Art

Many HDDs are screwed to brackets in computers, so the HDDs are rigidly connected to chassis, which means any vibrations to the chassis are easily transferred to the HDDs. When an HDD is operating at high speed, such vibrations may harm the HDD.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device, together with a hard disk drive (HDD).

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

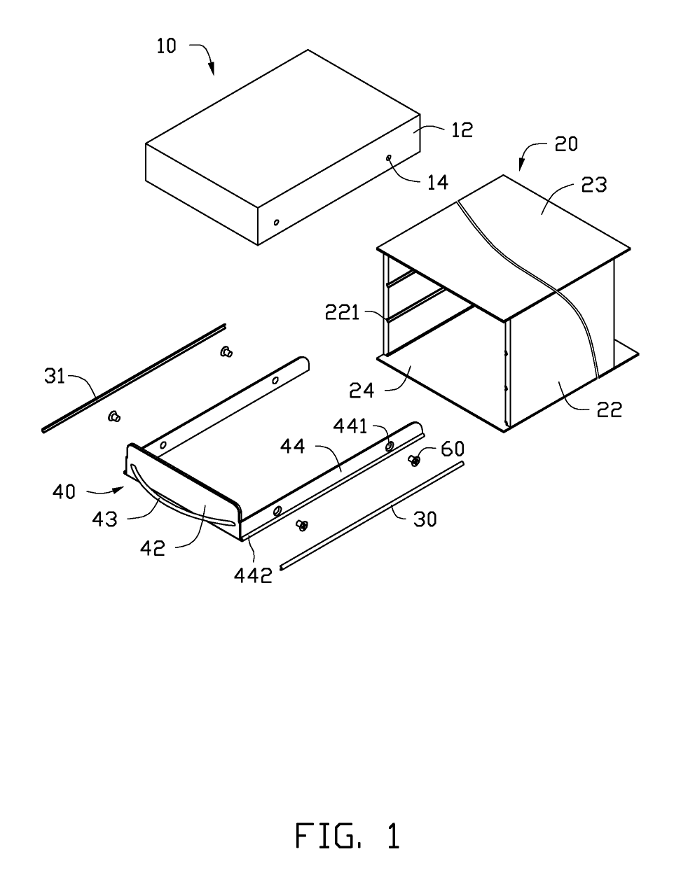

Referring to FIG. 1, an exemplary embodiment of a mounting device for mounting a hard disk drive (HDD) 10 includes a bracket 20, two shock absorbing members 30, and a slide member 40.

The HDD 10 includes two opposite sidewalls 12. Two locking holes 14 are defined in each sidewall 12.

The bracket 20 includes two opposite side plates 22, a top plate 23 connected between top sides of the side plates 22, and a bottom plate 24 connected between bottom sides of the side plates 22. A receiving slot 221 with a semicircular cross-section is defined in an inner surface of each side plate 22, parallel to the bottom plate 24 and extending through front and rear ends of the side plate 22.

Each shock absorbing member 30 is made of rubber. In other embodiments, the shock absorbing member 30 can be made of other resilient material, such as silica gel. The shock absorbing member 30 is arc-shaped in cross-section and elongated, and longitudinally defines a groove 31.

The slide member 40 includes a plate 42, an operation portion 43 extending from a front side of the plate 42, and two mounting plates 44 extending backward from opposite ends of the plate 42. Each mounting plate 44 defines two through holes 441. An elongated mounting portion 442 longitudinally extends out from each mounting plate 44, adjacent to a bottom of the mounting plate 44. The mounting portion 442 has an arc-shaped cross-section.

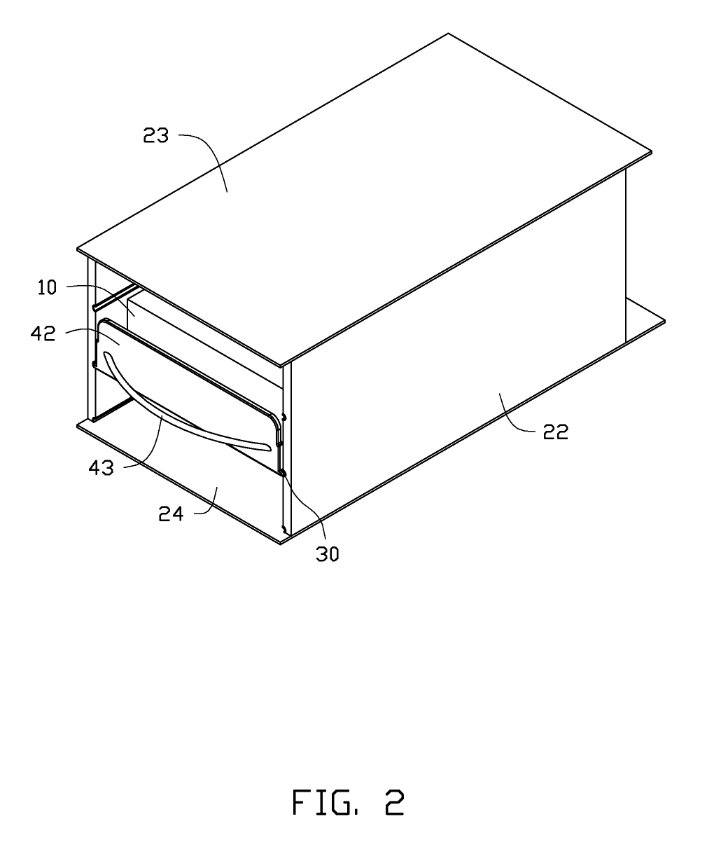

Referring to FIG. 2, in assembly, the HDD 10 is placed into the slide member 40, among the plate 42 and the mounting plates 44. The locking holes 14 are aligned with the corresponding through holes 441. Four screws 60 are respectively extended through the through holes 441 and engaged in the locking holes 14, to fix the HDD 10 in the slide member 40. The shock absorbing members 30 are respectively engaged in the receiving slots 221, with the groove 31 of each shock absorbing member 30 facing the other shock absorbing member 30. The mounting portions 442 slidably engage in the corresponding grooves 31. The HDD 10 together with the slide member 40 can be received in the bracket 20 by pushing the operation portion 43 backward.

Because the shock absorbing members 30 are made of rubber, vibrations of the HDD 10 and the bracket 20 can be dampened by the shock absorbing members 30.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for mounting a hard disk drive, comprising:
a bracket comprising two opposite side plates, an inner surface of each side plate defining a receiving slot;
two shock absorbing members made of resilient material and respectively received in the two receiving slots, each shock absorbing member defining a groove facing the other shock absorbing member; and
a slide member comprising two mounting plates to be respectively fixed to opposite sides of the hard disk drive, a mounting portion extending from each mounting plate to slidably engage in the groove of the corresponding shock absorbing member.

2. The mounting device of claim 1, wherein the slide member further comprises a plate connected between front ends of the mounting plates, an operation portion extends from a front side of the plate.

3. The mounting device of claim 1, wherein the shock absorbing members are made of rubber or silica gel.

4. The mounting device of claim 1, wherein the bracket further comprises a top plate connected between top sides of the side plates, and a bottom plate connected between bottom sides of the side plates.
